(19) United States
(12) Patent Application Publication
(10) Pub. No.: US 2025/0372477 A1
(43) Pub. Date: Dec. 4, 2025

(54) CHIP ASSEMBLY AND ELECTRONIC DEVICE

(71) Applicant: Wistron NeWeb Corporation, Hsinchu (TW)

(72) Inventors: Kang-Wei HUANG, Hsinchu (TW); Yu-Fu KU, Hsinchu (TW); Hsiang-Chao LIU, Hsinchu (TW); Chun-Hung YEH, Hsinchu (TW)

(21) Appl. No.: 19/013,076

(22) Filed: Jan. 8, 2025

(30) Foreign Application Priority Data
May 29, 2024 (TW) 113119819

(51) Int. Cl. H01L 23/367; H01L 23/552; H01L 25/07

(52) U.S. Cl. CPC H01L 23/3675; H01L 23/552; H01L 25/072

(57) ABSTRACT

A chip assembly includes a first chip and a first heat-conducting element. The first chip includes a first chip surface, which has a first chip area. The first heat-conducting element includes a first heat inflow surface, which has a first heat-conducting area. The first heat inflow surface is connected to the first chip surface, and an area ratio of the first heat-conducting area to the first chip area is less than 0.85.

### RELATED APPLICATIONS

This application claims the benefit of priority to Taiwan Patent Application Serial No. 113119819, filed on May 29, 2024. The entire content of the above identified application is incorporated herein by reference.

### BACKGROUND

### Technical Field

The present disclosure relates to a chip assembly and an electronic device, and more particularly to a chip assembly and an electronic device having a heat-conducting element.

### Description of Related Art

With the current trend in technological development, the number of chips in electronic devices is increasing, and the density of components is becoming higher. As a result, the thermal management and electrical design of electronic devices face severe challenges. For example, the RF (Radio Frequency) modules in electronic devices need to meet thermal requirements while also avoiding de-sense issues.

In view of this, there is an urgent need in the current market for chip assemblies and electronic devices that can simultaneously meet thermal requirements, electrical specifications, and have the advantage of low cost.

### SUMMARY

In one aspect, the present disclosure provides a chip assembly that includes a first chip and a first heat-conducting element. The first chip includes a first chip surface having a first chip area. The first heat-conducting element includes a first heat inflow surface having a first heat-conducting area. The first heat inflow surface is connected to the first chip surface, and an area ratio of the first heat-conducting area to the first chip area is less than 0.85.

In another aspect, the present disclosure provides an electronic device that includes the aforementioned chip assembly.

In yet another aspect, the present disclosure provides a chip assembly that has a stacking direction and includes a first chip and a first heat-conducting element. The first heat-conducting element is connected to the first chip along the stacking direction. When observed along the stacking direction, a projection area of the first heat-conducting element does not exceed a projection area of the first chip, and a first projection ratio of the projection area of the first heat-conducting element to the projection area of the first chip is less than 0.85.

### BRIEF DESCRIPTION OF THE DRAWINGS

The present disclosure can be more fully understood by reading the following detailed description of the embodiment, with reference made to the accompanying drawings as follows:

FIG. 1A is a schematic view of a chip assembly according to a first embodiment of the present disclosure.

FIG. 1B is a schematic view of a first projection ratio of the chip assembly shown in FIG. 1A.

FIG. 1C, FIG. 1D, and FIG. 1E are schematic views of the first projection ratios of the chip assemblies according to other embodiments of the present disclosure.

FIG. 2 is a schematic view of a chip assembly according to a second embodiment of the present disclosure.

FIG. 3 is a schematic view of a chip assembly according to a third embodiment of the present disclosure.

FIG. 4 is a schematic view of a chip assembly according to a fourth embodiment of the present disclosure.

FIG. 5 is a schematic view of a chip assembly according to a fifth embodiment of the present disclosure.

FIG. 6 is a schematic view of a chip assembly according to a sixth embodiment of the present disclosure.

FIG. 7 is a schematic view of an electronic device according to a seventh embodiment of the present disclosure.

### DETAILED DESCRIPTION

The present disclosure is more particularly described in the following embodiments that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of embodiments anywhere in this specification including embodiments of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

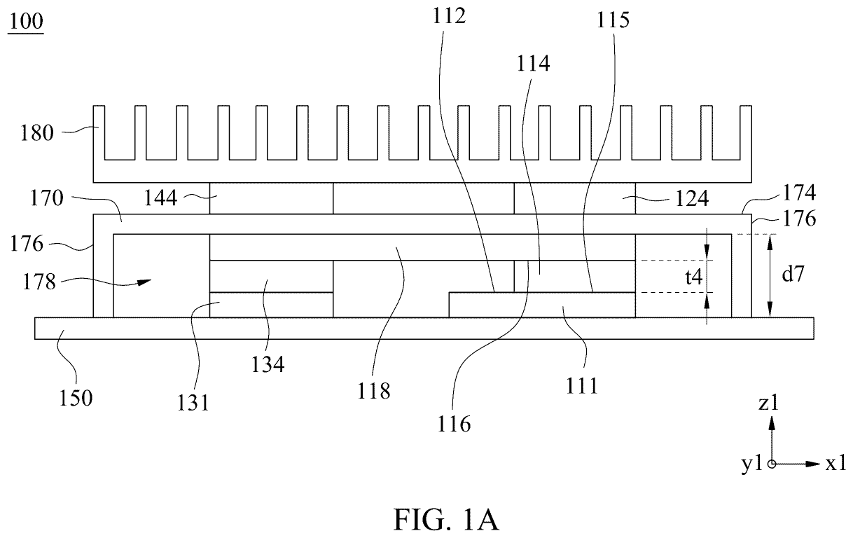

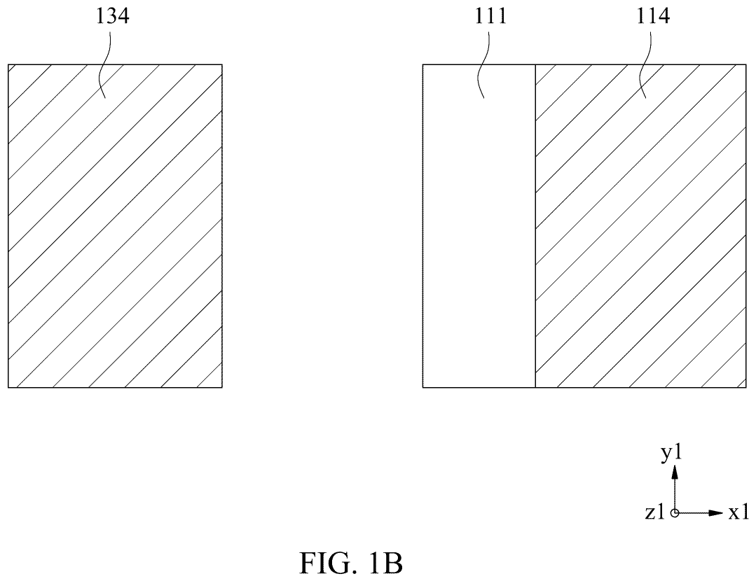

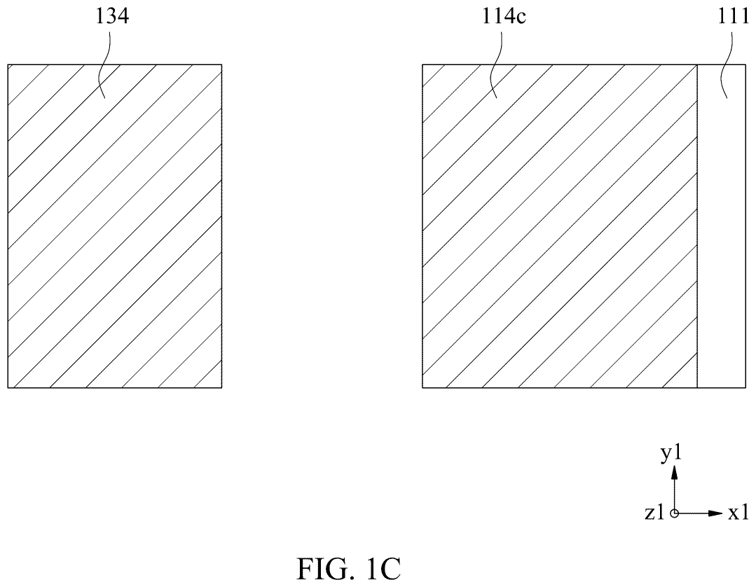

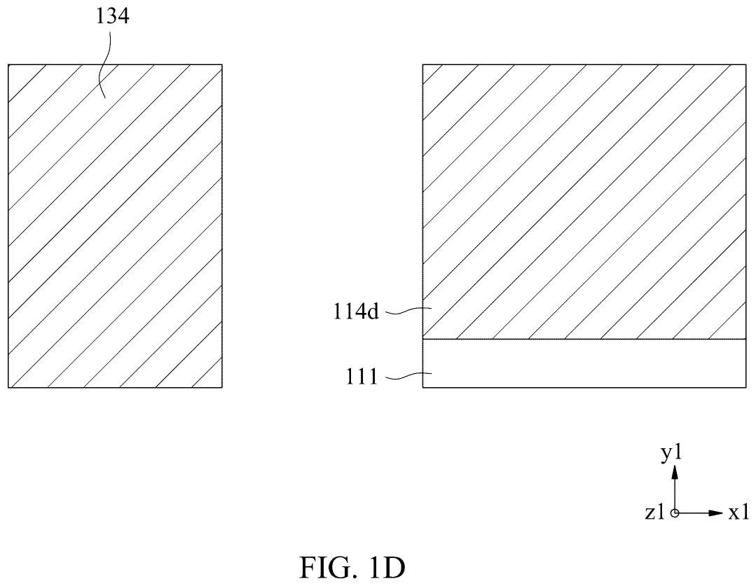

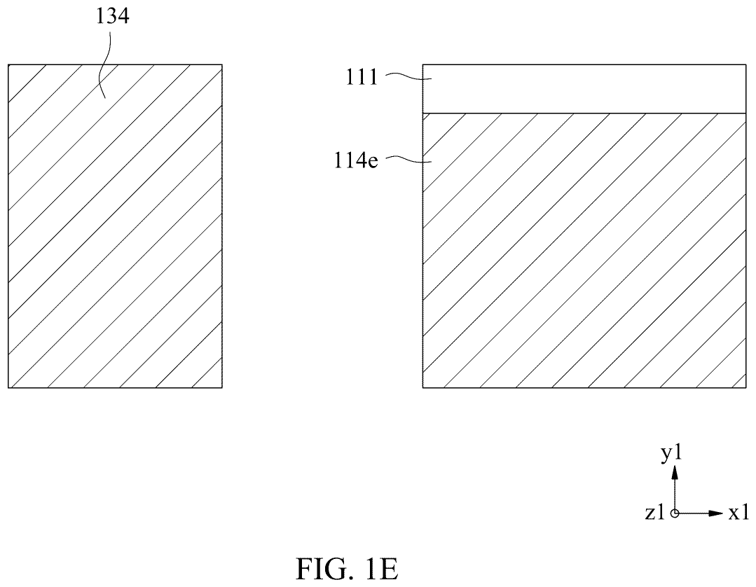

FIG. 1A is a schematic view of a chip assembly 100 according to the first embodiment of the present disclosure, and is also a front view observed along the second direction y1. Referring to FIG. 1A, the chip assembly 100 includes a first chip 111 and a first heat-conducting element 114. The first chip 111 includes a first chip surface 112, which has a normal direction parallel to a stacking direction z1 and has a first chip area. The first heat-conducting element 114 includes a first heat inflow surface 115, which has a normal direction parallel to the stacking direction z1 and has a first heat-conducting area. The first heat inflow surface 115 is directly connected to the first chip surface 112, and the area ratio of the first heat-conducting area to the first chip area is less than 0.85. This configuration simultaneously meets the thermal and electrical requirements of the chip assembly 100 and its first chip 111. Furthermore, the “chip” as disclosed herein can be a “chipset” and can be a packaged product including at least one integrated circuit, and the “chip assembly” as disclosed herein can be a module or part of a module that includes at least one aforementioned chip.

FIG. 1B is a schematic view of a first projection ratio of the chip assembly 100 shown in FIG. 1A, and is also a top view of the first chip 111 and the first heat-conducting element 114 observed along the stacking direction z1. Referring further to FIGS. 1A and 1B, the chip assembly 100 has the stacking direction z1 and includes the first chip 111 and the first heat-conducting element 114. The first heat-conducting element 114 is directly connected to the first chip 111 along the stacking direction z1. When (being) observed along the stacking direction z1, the projection area of the first heat-conducting element 114 does not exceed the projection area of the first chip 111, and the first projection ratio of the projection area of the first heat-conducting element 114 to the projection area of the first chip 111 is less than 0.85. This ensures that both the thermal and electrical requirements of the chip assembly 100 and its first chip 111 are met. Specifically, the first heat-conducting element 114 is aligned with the first chip 111 on the positive direction of a first direction x1 (i.e., the right side edge of the first chip 111 in FIG. 1B). The first projection ratio is defined as 0 at the right side edge of the first chip 111 in FIG. 1B and extends or covers towards the left side edge without reaching 0.85. Furthermore, the area ratio of the first heat-conducting area to the first chip area of the chip assembly 100 of the first embodiment is less than 0.85, as shown in FIG. 1B.

FIGS. 1C, 1D, and 1E are schematic views of the first projection ratios of chip assemblies in other embodiments of the present disclosure. Referring to FIG. 1C, the first heat-conducting element 114c is aligned with the first chip 111 at the left side edge of the first chip 111 in FIG. 1C. The first projection ratio is defined as 0 at the left side edge of the first chip 111 in FIG. 1C and extends towards the right side edge without reaching 0.85. Referring to FIG. 1D, the first heat-conducting element 114d is aligned with the first chip 111 at the upper side edge of the first chip 111 in FIG. 1D. The first projection ratio is defined as 0 at the upper side edge of the first chip 111 in FIG. 1D and extends towards the lower side edge without reaching 0.85. Referring to FIG. 1E, the first heat-conducting element 114e is aligned with the first chip 111 at the lower side edge of the first chip 111 in FIG. 1E. The first projection ratio is defined as 0 at the lower side edge of the first chip 111 in FIG. 1E and extends towards the upper side edge without reaching 0.85. Furthermore, it should be understood that the first chip, the first heat-conducting element, the second chip, and the second heat-conducting element of the chip assembly according to the present disclosure are not limited to square or rectangular shapes, and the spacing, size relationships, alignment conditions, and specific implementations of the first projection ratios are not limited to those shown in FIGS. 1B to 1E.

Specifically, referring to FIGS. 1A and 1B, the area ratio of the first heat-conducting area to the first chip area can be greater than 0.5 and less than 0.85. When observed along the stacking direction z1, the first projection ratio of the projection area of the first heat-conducting element 114 to the projection area of the first chip 111 can be greater than 0.5 and less than 0.85. This helps to further suppress crosstalk interference between the first chip 111 and neighboring chips (such as a second chip 131). Furthermore, the area ratio can be greater than 0.6 and less than 0.85, and the first projection ratio can be greater than 0.6 and less than 0.85. Additionally, the area ratio can be greater than 0.7 and less than 0.8, and the first projection ratio can be greater than 0.7 and less than 0.8.

The first heat-conducting element 114 may further include a first heat outflow surface 116, which is disposed opposite to the first heat inflow surface 115. The chip assembly 100 may further include a first wave-absorbing material 118, which is an electromagnetic wave absorbing material (EMI absorber). The first heat outflow surface 116 is directly connected to the first wave-absorbing material 118. This arrangement helps to absorb interference signals from neighboring chips and assists in heat dissipation, thereby reducing the thickness t4 and the amount of the first heat-conducting element 114, and achieving a design that balances heat dissipation, electrical performance, and low cost.

The thermal conductivity of the first heat-conducting element 114 can be equal to or greater than 0.5 W/mK, and the insertion loss (transmission loss, S21 parameter) of the first wave-absorbing material 118 can be less than-10 dB. This improves the thermal and electrical characteristics of the first chip 111. Specifically, the first heat-conducting element 114 can be a thermal interface material (TIM), such as a thermal pad, thermal putty, or thermal grease, and its thermal conductivity can be equal to or greater than 5 W/mK. The first wave-absorbing material 118 can be in the form of an adhesive or spray coating, with an insertion loss of less than-10 dB for 2.4 GHz electromagnetic waves and less than-15 dB for 5.0 GHz electromagnetic waves.

The chip assembly 100 may further include a circuit board 150, and the circuit board 150, the first chip 111, and the first heat-conducting element 114 are sequentially connected along the stacking direction z1. Furthermore, the first chip 111 can be a radio frequency chip or a radio frequency chipset. This helps the first chip 111 meet heat dissipation requirements and resolve the issue of reduced receiving sensitivity (de-sense). For example, the first chip 111 can be a WiSoC (Wi-Fi system on chip), but the present disclosure is not limited thereto.

The chip assembly 100 may further include a shielding cover 170, and the first heat outflow surface 116 is indirectly connected to the shielding cover 170. The shielding cover 170 is an electromagnetic shielding cover and includes a top section 174 and multiple side sections 176. The top section 174, the side sections 176, and the circuit board 150 are connected to form a closed shielding space 178. The first chip 111, the first heat-conducting element 114, and the first wave-absorbing material 118 are disposed in the shielding space 178. The circuit board 150, the first chip 111, the first heat-conducting element 114, and the shielding cover 170 are sequentially connected along the stacking direction z1. Furthermore, the distance d7 between the shielding cover 170 and the circuit board 150 can be equal to or less than 4 mm, and the thickness t4 of the first heat-conducting element 114 can be less than 1 mm. As such, the first heat-conducting element 114, the first wave-absorbing material 118, and the shielding cover 170 form an effective heat conduction path for the first chip 111 while reducing electromagnetic interference.

The chip assembly 100 may further include a fourth heat-conducting element 124. Specifically, the circuit board 150, the first chip 111, the first heat-conducting element 114, the first wave-absorbing material 118, the shielding cover 170, the fourth heat-conducting element 124, and a heat sink 180 are sequentially connected along the stacking direction z1. The heat sink 180 can be a finned heat sink, but the present disclosure is not limited thereto. Thus, the heat conduction path is extended beyond the limited shielding space 178, thereby enhancing heat dissipation.

The chip assembly 100 may further include a second chip 131 and a second heat-conducting element 134. The second chip 131 is disposed separately from the first chip 111 in a vertical direction of the stacking direction z1. The circuit board 150, the second chip 131, the second heat-conducting element 134, and the shielding cover 170 are sequentially connected along the stacking direction z1. This configuration helps design for the individual needs of the first chip 111 and the second chip 131, so as to improve the thermal and electrical characteristics of the chip assembly 100. Furthermore, the second chip 131 can be a memory, such as a double data rate synchronous dynamic random-access memory (DDR SDRAM), but the present disclosure is not limited thereto. Additionally, when observed along the stacking direction z1, a second projection ratio of the projection area of the second heat-conducting element 134 to the projection area of the second chip 131 can be between 0.5 and 1, with the specific second projection ratio in the first embodiment being 1, as shown in FIG. 1B, and the projection area of the second heat-conducting element 134 overlaps with the projection area of the second chip 131.

The circuit board 150, the first chip 111, the first heat-conducting element 114, the first wave-absorbing material 118, the shielding cover 170, the fourth heat-conducting element 124, and the heat sink 180 are sequentially connected along the stacking direction z1. The circuit board 150, the second chip 131, the second heat-conducting element 134, the first wave-absorbing material 118, the shielding cover 170, a heat-conducting element 144, the heat sink 180 are sequentially connected along the stacking direction z1, and the first chip 111 and the second chip 131 are both indirectly connected to the first wave-absorbing material 118. This configuration reduces the complexity of the manufacturing process.

The first heat-conducting element 114 can be close to or further aligned with the side of the first chip 111 that is far from the second chip 131. This configuration helps reduce interference between the first chip 111 and the second chip 131. Specifically, the second chip 131 is disposed in the negative direction of the first direction x1 relative to the first chip 111, and the first heat-conducting element 114 is aligned with the first chip 111 in the positive direction of the first direction x1 (as shown in FIGS. 1A and 1B), and the first direction x1, the second direction y1, and the stacking direction z1 are perpendicular to each other.

When observed along the stacking direction z1, one side of the projection area of the first heat-conducting element 114 along the first direction x1 can be aligned with one side of the projection area of the first chip 111 along the first direction x1. This configuration helps to reduce interference and design complexity. Additionally, when observed along the stacking direction z1, the projection area of the first heat-conducting element 114 on one side along the second direction y1 can be aligned or not aligned with the projection area of the first chip 111 on the same side along the second direction y1.

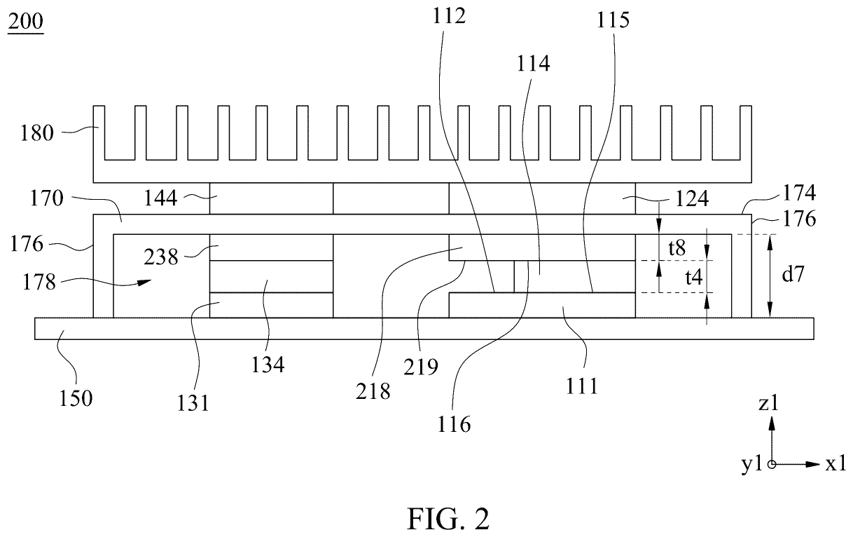

FIG. 2 is a schematic view of a chip assembly 200 according to the second embodiment of the present disclosure, and is also a front view observed along the second direction y1. Referring to FIG. 2, the chip assembly 200 has a stacking direction z1 and includes a first chip 111 and a first heat-conducting element 114. The first chip 111 includes a first chip surface 112, which has a normal direction parallel to the stacking direction z1 and has a first chip area. The first heat-conducting element 114 includes a first heat inflow surface 115, which has a normal direction parallel to the stacking direction z1 and has a first heat-conducting area. The first heat inflow surface 115 is directly connected to the first chip surface 112 along the stacking direction z1, and the area ratio of the first heat-conducting area to the first chip area is less than 0.85. When observed along the stacking direction z1, the projection area of the first heat-conducting element 114 does not exceed the projection area of the first chip 111, and the first projection ratio of the projection area of the first heat-conducting element 114 to the projection area of the first chip 111 is less than 0.85.

Specifically, in the second embodiment, the circuit board 150, the first chip 111, the first heat-conducting element 114, the first wave-absorbing material 218, the shielding cover 170, the fourth heat-conducting element 124, and the heat sink 180 are sequentially connected along the stacking direction z1. The circuit board 150, the second chip 131, the second heat-conducting element 134, a second wave-absorbing material 238, the shielding 170, the heat-conducting element 144, and the heat sink 180 are sequentially connected along the stacking direction z1. The first chip 111 and the second chip 131 are indirectly connected to the first wave-absorbing material 218 and the second wave-absorbing material 238, respectively. In the embodiments of the present disclosure, the first chip and the second chip can both be connected to the first wave-absorbing material, or the first chip and the second chip can be respectively connected to the first wave-absorbing material and the second wave-absorbing material.

The volume ratio of the volume of the first heat-conducting element 114 to the volume of the first wave-absorbing material 218 can be greater than 1 and less than 1.7, where the volume of the first heat-conducting element 114 is the product of the thickness t4 and the area of the first heat outflow surface 116, and the volume of the first wave-absorbing material 218 is the product of the thickness t8 and the area of the first wave-absorbing surface 219. As such, heat dissipation characteristics which are more effective are achieved. Additionally, when observed along the stacking direction z1, the first absorbing projection ratio of the projection area of the first wave-absorbing material 218 to the projection area of the first chip 111 can be between 0.5 and 1.5, with the specific first absorbing projection ratio in the second embodiment being 1.

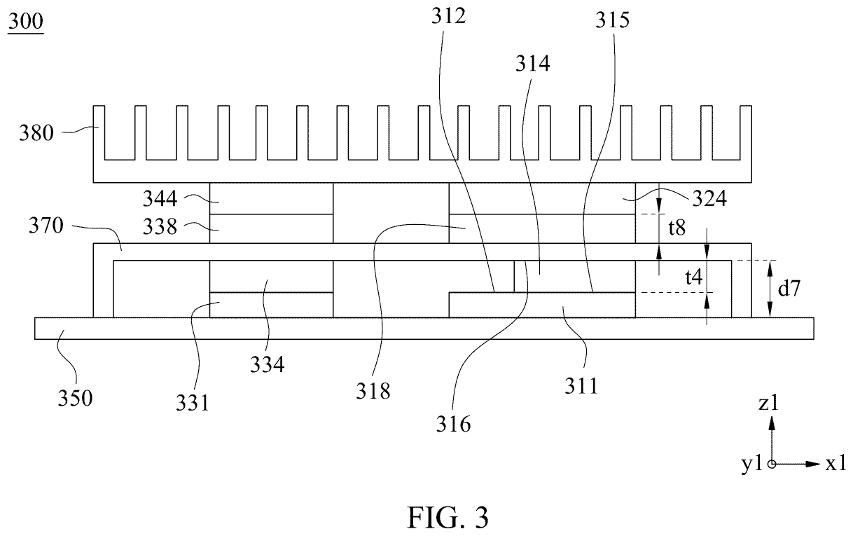

FIG. 3 is a schematic view of a chip assembly 300 according to the third embodiment of the present disclosure, and is also a front view observed along the second direction y1. Referring to FIG. 3, the chip assembly 300 has a stacking direction z1 and includes a first chip 311 and a first heat-conducting element 314. The first chip 311 includes a first chip surface 312, which has a normal direction parallel to the stacking direction z1 and has a first chip area. The first heat-conducting element 314 includes a first heat inflow surface 315, which has a normal direction parallel to the stacking direction z1 and has a first heat-conducting area. The first heat inflow surface 315 is directly connected to the first chip surface 312 along the stacking direction z1, and the area ratio of the first heat-conducting area to the first chip area is less than 0.85. When observed along the stacking direction z1, the projection area of the first heat-conducting element 314 does not exceed the projection area of the first chip 311, and the first projection ratio of the projection area of the first heat-conducting element 314 to the projection area of the first chip 311 is less than 0.85.

Specifically, the chip assembly 300 further includes a first wave-absorbing material 318, and the circuit board 350, the first chip 311, the first heat-conducting element 314, the shielding cover 370, and the first wave-absorbing material 318 are sequentially connected along the stacking direction z1. This configuration increases design flexibility while ensuring heat dissipation and electrical characteristics.

In the third embodiment, the first heat-conducting element 314 further includes a first heat outflow surface 316, which is disposed opposite to the first heat inflow surface 315. The first heat outflow surface 316 is indirectly connected to the first wave-absorbing material 318. The circuit board 350, the first chip 311, the first heat-conducting element 314, the shielding cover 370, the first wave-absorbing material 318, the fourth heat-conducting element 324, and the heat sink 380 are sequentially connected along the stacking direction z1. The circuit board 350, the second chip 331, the second heat-conducting element 334, the shielding cover 370, the second wave-absorbing material 338, the heat-conducting element 344, and the heat sink 380 are sequentially connected along the stacking direction z1. The first chip 311 and the second chip 331 are indirectly connected to the first wave-absorbing material 318 and the second wave-absorbing material 338, respectively. The volume ratio of the volume of the first heat-conducting element 314 to the volume of the first wave-absorbing material 318 is greater than 1 and less than 1.7.

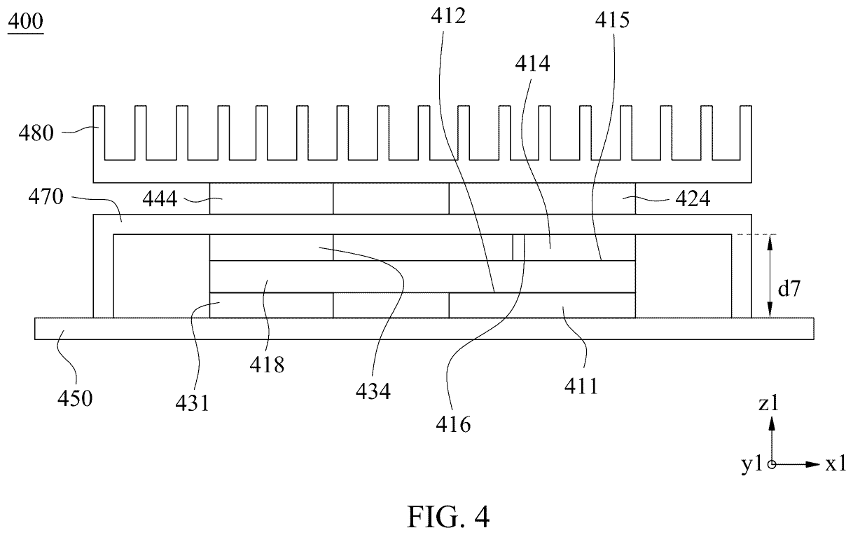

FIG. 4 is a schematic view of a chip assembly 400 according to the fourth embodiment of the present disclosure, and is also a front view observed along the second direction y1. Referring to FIG. 4, the chip assembly 400 includes a first chip 411 and a first heat-conducting element 414. The first chip 411 includes a first chip surface 412, which has a normal direction parallel to the stacking direction z1 and has a first chip area. The first heat-conducting element 414 includes a first heat inflow surface 415, which has a normal direction parallel to the stacking direction z1 and has a first heat-conducting area. The first heat inflow surface 415 is indirectly connected to the first chip surface 412, and the area ratio of the first heat-conducting area to the first chip area is less than 0.85.

Furthermore, the chip assembly 400 has the stacking direction z1 and includes the first chip 411 and the first heat-conducting element 414. The first heat-conducting element 414 is indirectly connected to the first chip 411 along the stacking direction z1. When observed along the stacking direction z1, the projection area of the first heat-conducting element 414 does not exceed the projection area of the first chip 411, and the first projection ratio of the projection area of the first heat-conducting element 414 to the projection area of the first chip 411 is less than 0.85.

Specifically, the chip assembly 400 further includes a first wave-absorbing material 418, which is directly connected between the first heat inflow surface 415 and the first chip surface 412. This configuration increases design flexibility while ensuring heat dissipation and electrical characteristics.

In the fourth embodiment, the first heat-conducting element 414 further includes a first heat outflow surface 416, which is disposed opposite to the first heat inflow surface 415. The first heat outflow surface 416 is indirectly connected to the first wave-absorbing material 418. The circuit board 450, the first chip 411, the first wave-absorbing material 418, the first heat-conducting element 414, the shielding cover 470, the fourth heat-conducting element 424, and the heat sink 480 are sequentially connected along the stacking direction z1. The circuit board 450, the second chip 431, the first wave-absorbing material 418, the second heat-conducting element 434, the shielding cover 470, the heat-conducting element 444, and the heat sink 480 are sequentially connected along the stacking direction z1. The first chip 411 and the second chip 431 are both directly connected to the first wave-absorbing material 418.

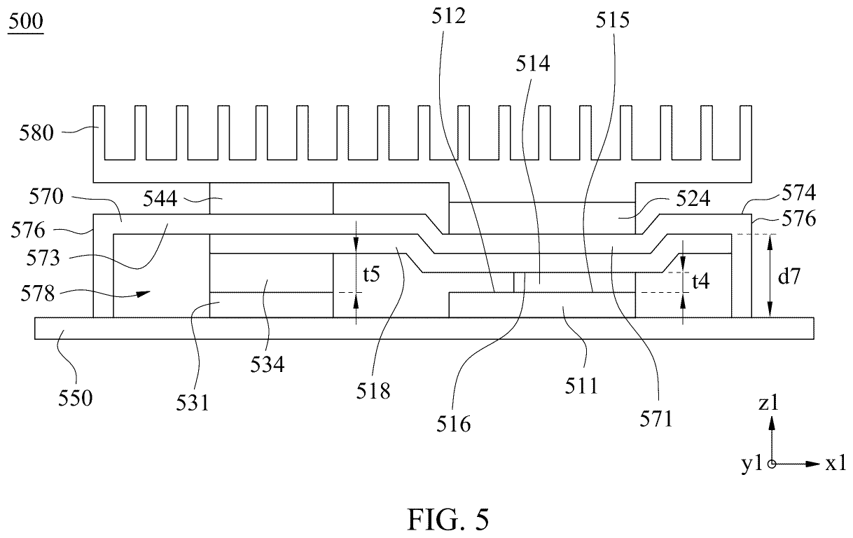

FIG. 5 is a schematic view of a chip assembly 500 according to the fifth embodiment of the present disclosure, and is also a front view observed along the second direction y1. Referring to FIG. 5, the chip assembly 500 has a stacking direction z1 and includes a first chip 511 and a first heat-conducting element 514. The first chip 511 includes a first chip surface 512, which has a normal direction parallel to the stacking direction z1 and has a first chip area. The first heat-conducting element 514 includes a first heat inflow surface 515, which has a normal direction parallel to the stacking direction z1 and has a first heat-conducting area. The first heat inflow surface 515 is directly connected to the first chip surface 512 along the stacking direction z1, and the area ratio of the first heat-conducting area to the first chip area is less than 0.85. When observed along the stacking direction z1, the projection area of the first heat-conducting element 514 does not exceed the projection area of the first chip 511, and the first projection ratio of the projection area of the first heat-conducting element 514 to the projection area of the first chip 511 is less than 0.85.

Specifically, the first heat-conducting element 514 further includes a first heat outflow surface 516, which is disposed opposite to the first heat inflow surface 515. The first heat outflow surface 516 is directly connected to the first wave-absorbing material 518.

The shielding cover 570 is an electromagnetic shielding cover and includes a top section 574 and four side sections 576. The top section 574, the side sections 576, and the circuit board 550 are connected to form a closed shielding space 578. The first chip 511, the first heat-conducting element 514, the first wave-absorbing material 518, the second chip 531, and the second heat-conducting element 534 are disposed in the shielding space 578. The top section 574 includes a main body portion 573 and a recessed portion 571, and the distance between the recessed portion 571 and the circuit board 550 is less than the distance d7 between the main body portion 573 and the circuit board 550.

In the fifth embodiment, the circuit board 550, the first chip 511, the first heat-conducting element 514, the first wave-absorbing material 518, the recessed portion 571 of the shielding cover 570, the fourth heat-conducting element 524, and the heat sink 580 are sequentially connected along the stacking direction z1. The circuit board 550, the second chip 531, the second heat-conducting element 534, the first wave-absorbing material 518, the main body portion 573 of the shielding cover 570, the heat-conducting element 544, and the heat sink 580 are sequentially connected along the stacking direction z1, with the thickness t4 of the first heat-conducting element 514 being less than the thickness t5 of the second heat-conducting element 534. By reducing the distance between the first chip 511 and the recessed portion 571 of the shielding cover 570, the thickness t4 of the first heat-conducting element 514 can be reduced, thereby shortening the heat dissipation path and improving the heat dissipation capability of the first chip 511.

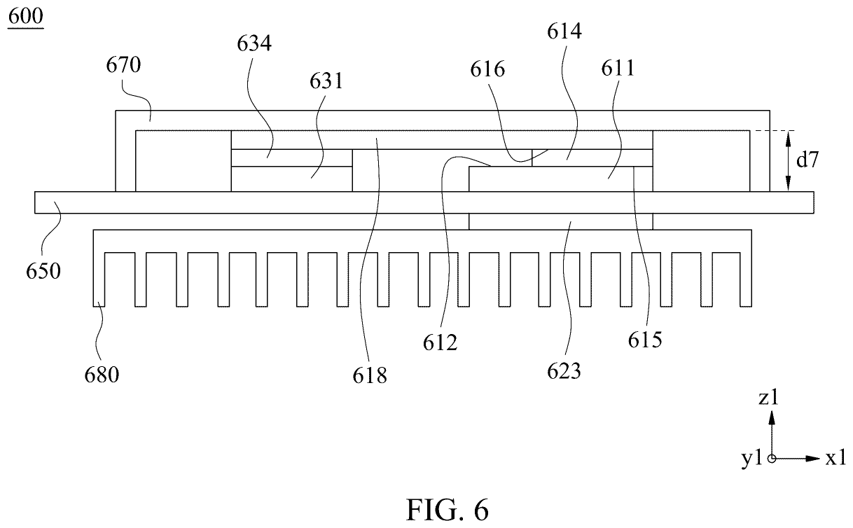

FIG. 6 is a schematic view of a chip assembly 600 according to the sixth embodiment of the present disclosure, and is also a front view observed along the second direction y1. Referring to FIG. 6, the chip assembly 600 has a stacking direction z1 and includes a first chip 611 and a first heat-conducting element 614. The first chip 611 includes a first chip surface 612, which has a normal direction parallel to the stacking direction z1 and has a first chip area. The first heat-conducting element 614 includes a first heat inflow surface 615, which has a normal direction parallel to the stacking direction z1 and has a first heat-conducting area. The first heat inflow surface 615 is directly connected to the first chip surface 612 along the stacking direction z1, and the area ratio of the first heat-conducting area to the first chip area is less than 0.85. When observed along the stacking direction z1, the projection area of the first heat-conducting element 614 does not exceed the projection area of the first chip 611, and the first projection ratio of the projection area of the first heat-conducting element 614 to the projection area of the first chip 611 is less than 0.85.

Specifically, the first heat-conducting element 614 further includes a first heat outflow surface 616, which is disposed opposite to the first heat inflow surface 615. The first heat outflow surface 616 is directly connected to the first wave-absorbing material 618.

The chip assembly 600 further includes a third heat-conducting element 623, and the third heat-conducting element 623, the circuit board 650, the first chip 611, and the first heat-conducting element 614 are sequentially connected along the stacking direction z1. This configuration allows the first chip 611 to conduct heat through the via on the circuit board 650 to the third heat-conducting element 623, thereby enhancing heat dissipation.

In the sixth embodiment, the heat sink 680, the third heat-conducting element 623, the circuit board 650, the first chip 611, the first heat-conducting element 614, the first wave-absorbing material 618, and the shielding cover 670 are sequentially connected along the stacking direction z1. The circuit board 650, the second chip 631, the second heat-conducting element 634, the first wave-absorbing material 618, and the shielding cover 670 are sequentially connected along the stacking direction z1. The first chip 611 and the second chip 631 are both indirectly connected to the first wave-absorbing material 618.

The description of the chip assembly 100 in the first embodiment can be referred for other details of the chip assemblies 200, 300, 400, 500, 600 in the second to sixth embodiments, which will not be detailed herein.

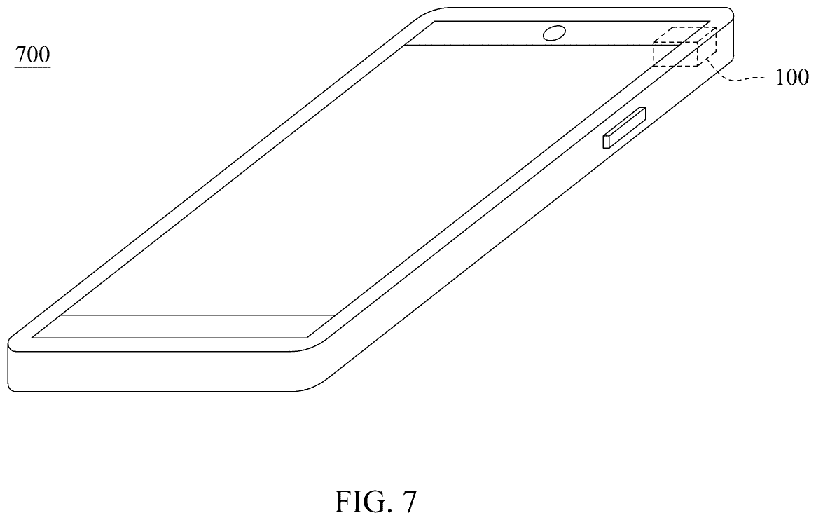

FIG. 7 is a schematic view of an electronic device 700 according to the seventh embodiment of the present disclosure. Referring to FIG. 7, the electronic device 700 includes a chip assembly according to the present disclosure, such as any one of the aforementioned chip assemblies 100, 200, 300, 400, 500, 600. Specifically, the electronic device 700 can be a smartphone, but the present disclosure is not limited thereto. By enhancing the heat dissipation and electrical characteristics of the chip assembly 100 within the electronic device 700, the performance and reliability of the electronic device 700 can be improved.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A chip assembly, comprising:
a first chip, comprising a first chip surface having a first chip area; and
a first heat-conducting element, comprising a first heat inflow surface having a first heat-conducting area, wherein the first heat inflow surface is connected to the first chip surface, and an area ratio of the first heat-conducting area to the first chip area is less than 0.85.

2. The chip assembly according to claim 1, wherein the area ratio is greater than 0.5 and less than 0.85.

3. The chip assembly according to claim 1, wherein the first heat-conducting element further comprises a first heat outflow surface disposed opposite to the first heat inflow surface, the chip assembly further comprises a first wave-absorbing material, and the first heat outflow surface is connected to the first wave-absorbing material.

4. The chip assembly according to claim 3, wherein a volume ratio of a volume of the first heat-conducting element to a volume of the first wave-absorbing material is greater than 1 and less than 1.7.

5. The chip assembly according to claim 3, wherein a thermal conductivity of the first heat-conducting element is equal to or greater than 0.5 W/mK, and an insertion loss of the first wave-absorbing material is less than-10 dB.

6. The chip assembly according to claim 1, wherein the first heat-conducting element further comprises a first heat outflow surface disposed opposite to the first heat inflow surface, and the chip assembly further comprises:
a shielding cover, wherein the first heat outflow surface is connected to the shielding cover.

7. The chip assembly according to claim 1, further comprising:
a first wave-absorbing material, connected between the first heat inflow surface and the first chip surface.

8. An electronic device, comprising:
the chip assembly according to claim 1.

9. A chip assembly, having a stacking direction and comprising:
a first chip; and
a first heat-conducting element, connected to the first chip along the stacking direction;
wherein, when observed along the stacking direction, a projection area of the first heat-conducting element does not exceed a projection area of the first chip, and a first projection ratio of the projection area of the first heat-conducting element to the projection area of the first chip is less than 0.85.

10. The chip assembly according to claim 9, wherein the first projection ratio is greater than 0.5 and less than 0.85.

11. The chip assembly according to claim 9, wherein, when observed along the stacking direction, one side of the projection area of the first heat-conducting element along a first direction aligns with one side of the projection area of the first chip along the first direction, and the first direction is perpendicular to the stacking direction.

12. The chip assembly according to claim 9, further comprising:
a circuit board, wherein the circuit board, the first chip, and the first heat-conducting element are sequentially connected along the stacking direction, and the first chip is a radio frequency chip.

13. The chip assembly according to claim 12, further comprising:
a third heat-conducting element, wherein the third heat-conducting element, the circuit board, the first chip, and the first heat-conducting element are sequentially connected along the stacking direction.

14. The chip assembly according to claim 12, further comprising:
a shielding cover, wherein the circuit board, the first chip, the first heat-conducting element, and the shielding cover are sequentially connected along the stacking direction, and a distance between the shielding cover and the circuit board is equal to or less than 4 mm.

15. The chip assembly according to claim 14, further comprising:
a first wave-absorbing material, wherein the circuit board, the first chip, the first heat-conducting element, the shielding cover, and the first wave-absorbing material are sequentially connected along the stacking direction.

16. The chip assembly according to claim 14, further comprising:
a fourth heat-conducting element, wherein the circuit board, the first chip, the first heat-conducting element, the shielding cover, and the fourth heat-conducting element are sequentially connected along the stacking direction.

17. The chip assembly according to claim 14, further comprising:
a second chip; and
a second heat-conducting element, wherein the circuit board, the second chip, the second heat-conducting element, and the shielding cover are sequentially connected along the stacking direction.

18. The chip assembly according to claim 17, wherein the first heat-conducting element is close to a side of the first chip that is far from the second chip.

19. The chip assembly according to claim 17, further comprising:
a first wave-absorbing material, wherein the circuit board, the first chip, the first heat-conducting element, and the first wave-absorbing material are sequentially connected along the stacking direction, and the circuit board, the second chip, the second heat-conducting element, and the first wave-absorbing material are sequentially connected along the stacking direction.

20. The chip assembly according to claim 17, wherein the shielding cover comprises a main body portion and a recessed portion, the circuit board, the first chip, the first heat-conducting element, and the recessed portion are sequentially connected along the stacking direction, the circuit board, the second chip, the second heat-conducting element, and the main body portion are sequentially connected along the stacking direction, a distance between the recessed portion and the circuit board is less than a distance between the main body portion and the circuit board, and a thickness of the first heat-conducting element is less than a thickness of the second heat-conducting element.
